(19) United States
(12) Patent Application Publication
(10) Pub. No.: US 2023/0173932 A1
(43) Pub. Date: Jun. 8, 2023

(54) METHOD FOR CHARGING AN ELECTRIC ENERGY ACCUMULATOR OF A MOTOR VEHICLE, THE MOTOR VEHICLE, AND A CHARGING STATION

(71) Applicant: AUDI AG, Ingolstadt (DE)

(72) Inventors: Christian REBINGER, Munchen (DE); Dirk SCHROEDER, Manching (DE)

(21) Appl. No.: 18/062,440

(22) Filed: Dec. 6, 2022

(30) Foreign Application Priority Data
Dec. 7, 2021 (DE) 102021132151.4

(51) Int. Cl. B60L 53/302; H05K 7/20

(52) U.S. Cl. CPC B60L 53/302; H05K 7/20936; H05K 7/20272; H05K 7/2039

(57) ABSTRACT

A method for charging at least one electric energy accumulator of a motor vehicle, wherein electric energy from a charging station external to the motor vehicle is transferred via a detachable electrical connection to the energy accumulator, wherein a cooling fluid is taken from the charging station via a detachable cooling fluid connection to at least one cooling element of the motor vehicle, so that thermal energy from the energy accumulator is transferred via the cooling element to the cooling fluid and taken away by the cooling fluid, wherein the liquid cooling fluid is mixed with a gas before and/or during its transfer to the cooling element, so that a cooling fluid/gas mixture is formed, wherein at least a portion of the cooling fluid is evaporated into gas during the transfer of the thermal energy from the energy accumulator to the cooling fluid.

### BACKGROUND

### Technical Field

Embodiments of the invention relate to a method for charging at least one electric energy accumulator of a motor vehicle, wherein electric energy from a charging station external to the motor vehicle is transferred via a detachable electrical connection to the energy accumulator, wherein a cooling fluid is taken from the charging station via a detachable cooling fluid connection to at least one cooling element of the motor vehicle, so that thermal energy from the energy accumulator is transferred via the cooling element to the cooling fluid and taken away by means of the cooling fluid.

### Description of the Related Art

Motor vehicles with rechargeable electric energy accumulators, such as batteries, which are associated with the operation of an electric motor and are known as traction batteries, are known in the prior art. Thus, in addition to pure electric vehicles in which the electric motor is the sole propulsion device, there are hybrid vehicles having in addition to the electric motor also another propulsion device, such as a combustion engine. In electric vehicles and so-called plug-in hybrids it is known that the motor vehicle has a charging terminal for connection to a charging station external to the motor vehicle, such as a stationary charging column. Using the charging station, electric energy is provided to the motor vehicle, such as from the public power grid, for the charging of the energy accumulators.

One problem in regard to electric energy accumulators of motor vehicles is that they become heated during certain operating phases, which makes necessary a corresponding battery cooling. One such operating phase is the driving phase, during which energy is provided from the energy accumulator to produce a driving power of the motor vehicle, thereby becoming discharged. A heating also occurs when charging the energy accumulator, this problem occurring during recuperation and more pronounced during so-called fast charging, when the empty energy accumulator reaches a state of charge adequate for continued driving already after a few minutes of charge time. A significantly greater heating of the energy accumulator occurs in this case, as compared to “normal” charging processes or driving operation.

Cooling systems are often provided at the motor vehicle side for the cooling of the energy accumulator, where a cooling is accomplished using a circulating cooling fluid and/or a flow of cooling air. However, the operation of the cooling system at the motor vehicle side by itself is often not enough, such as in the case of the described fast charging, to provide the cooling performance actually required. Regarding charging processes at charging stations, it is known in the prior art as the solution for this problem how to provide a cooling fluid at the charging column and supply this to the electric energy accumulator of the motor vehicle. Corresponding concepts are known from DE 10 2012 220 218 A1, DE 10 2010 007 975 A1, DE 10 2017 202 391 A1, U.S. Pat. No. 4,415,847 A and US 2020/0 343 610 A1.

### BRIEF SUMMARY

Some embodiments provide an improved or further developed concept in regard to the cooling of an electric energy accumulator of a motor vehicle during charging at a charging station.

In some embodiments, a liquid cooling fluid is brought together with a gas before and/or during the supplying to the cooling element, so that a cooling fluid/gas mixture is formed, wherein at least a portion of the cooling fluid evaporates into the gas during the transfer of the thermal energy from the energy accumulator to the cooling fluid.

In some embodiments, it is proposed that the transfer of the thermal energy from the energy accumulator via the cooling element to the cooling fluid not only brings about a simple heating of the cooling fluid, but also an evaporation of it. By evaporation is meant a transition occurring beneath the boiling temperature from the liquid to the gaseous state. Since a certain energy is needed for the evaporation process, also known as the evaporation enthalpy, this brings about a cooldown of the cooling fluid, so that more thermal energy can be taken away from the energy accumulator using the cooling fluid. The overall thermal energy which can be taken away using the cooling fluid is thus composed of the energy bringing about the heating of the liquid cooling fluid and the energy bringing about the evaporation of the cooling fluid.

Bringing together the liquid cooling fluid with the gas has the effect that the resulting cooling fluid/gas mixture comprises a liquid and a gaseous phase, so that the cooling fluid or the liquid phase can evaporate into the gaseous phase. The evaporation process is made possible in this case in that the gas which is supplied to the cooling fluid is not saturated with gaseous cooling fluid or cooling fluid vapor, so that the gas can take up the evaporating cooling fluid.

Although the charging station can be mobile, it may also be fixed in place or stationary, and the stationary charging station can also be called a fueling station or charging column. The charging station is connected to an energy source, such as a public power grid and/or a photovoltaic installation or the like. A charging cable is used to form the detachable electrical connection between the charging station and the motor vehicle, the connection being formed by corresponding plugs and sockets. The cable can be connected firmly to the vehicle or firmly to the charging station or the two may both have a corresponding detachable plug.

In some embodiments, water is used as the cooling fluid, since water is no problem from an ecology standpoint and it is especially cost-effective. Furthermore, water does not need to be preconditioned in regard to the conditions typically occurring in charging situations with regard to temperature and pressure in order to make possible the evaporation process. Ambient air may be used as the gas, especially since it is not only environmentally friendly, but also available in virtually unlimited quantity and thus at no cost.

The charging station may comprise a cooling fluid reservoir and/or be connected to a cooling fluid source. The cooling fluid reservoir may be a tank, such as a water tank. The cooling fluid can be replenished appropriately, for example, during regular servicing. This replenishing can take place by connecting the charging station to a water supply main. The cooling fluid source can be a public water supply grid and/or a rain water catchment, to which the charging is connected. In particular, the charging station may comprise both a cooling fluid reservoir and be connected to the cooling fluid source. Thus, the cooling fluid reservoir, as soon as or not later than when the fill level of the cooling fluid falls below a predetermined minimum fill level, can be automatically replenished by means of the cooling fluid from the cooling fluid source, for which electronic sensor, control, and valve devices can be provided. The automatic replenishing may occur by means of a float located in the cooling fluid reservoir on the model of a toilet flush tank.

The cooling fluid can be delivered or pumped by means of a cooling fluid delivery device such as a cooling fluid pump from the cooling fluid reservoir or the cooling fluid source to the cooling element. The cooling fluid delivery device may be a component of the charging station. But the cooling fluid delivery device can also be dispensed with, as long as the charging station is connected to the public water supply grid and the pipeline pressure is high enough to take the water to the motor vehicle.

In some methods, it can be provided that the gas is taken to the cooling fluid by means of a gas delivery device, the gas delivery device being a component of the motor vehicle or the charging station. The gas delivery device can be a gas delivery pump or a fan for drawing in the ambient air. If the gas is provided at least partially by means of a gas reservoir under a sufficiently high pressure, such as the charging station, then the corresponding gas pressure can support the flowing of the gas into the fluid. The gas delivery device may comprise an electrical or mechanical pressure reducing device, such as an expansion or throttle valve and/or a pressure reducer, and the pressure reducing device can dictate the correct proportioning or admixture pressure by means of which the gas flows into the fluid.

The cooling element can be a cooling plate making thermal contact with the energy accumulator. Upon heating of the energy accumulator, thermal energy is transferred to the cooling plate, while the cooling fluid in turn makes thermal contact with the cooling plate, so that the thermal energy is transferred to the cooling fluid. The cooling fluid or the mixture can flow through cooling ducts formed along a surface of the cooling plate. In addition or alternatively, the cooling plate can be riddled with cooling ducts through which the cooling fluid or the mixture flows.

The cooling element can be a heat exchanger, by means of which thermal energy is transferred to the cooling fluid from a coolant circulating in a cooling circuit for the cooling of the energy accumulator. The cooling circuit of the motor vehicle can either be provided exclusively for the transfer of thermal energy from the energy accumulator to the heat exchanger or as an active cooling circuit. “Active” means that a further cooling effect is provided by the cooling circuit itself, somewhat on the model of a refrigerating machine. The cooling circuit can be configured and provided in particular for the cooling of the energy accumulator in a driving operation of the motor vehicle. The cooling effect which can be realized by means of the cooling circuit is accordingly intensified during the charging process in the method described herein.

The energy accumulator may stand in thermal contact with at least one additional cooling element, which is incorporated in a separate cooling circuit. The separate cooling circuit can be operated independently of the cooling circuit. Both cooling elements and cooling circuits can therefore work independently of and separately from each other, the separate cooling circuit being provided in particular for the cooling of the energy accumulator in a driving operation of the motor vehicle.

In the method described herein, it can be provided that the cooling fluid/gas mixture is discharged partially or entirely into the surroundings after the transfer of the thermal energy. The cooling system formed in the context of the method described herein can be called in this embodiment an “open system,” since the cooling fluid does not circulate in a circuit. A discharging into the surroundings can be advantageous because it does not require any return line for the cooling fluid from the motor vehicle to the charging station and no corresponding means to realize this. In particular, when water is used as the cooling fluid and ambient air is used as the gas, this procedure is also no problem in terms of environmental protection.

One alternative to the just described “open system” is a “half-open” system, where a portion of the cooling fluid circulates, or a “closed system,” where the entire cooling fluid circulates. Thus, it can be provided in the method described herein that the cooling fluid/gas mixture is taken partly or entirely to a phase separator of the motor vehicle or the charging station after the transfer of the thermal energy. By means of the phase separator, a liquid phase of the cooling fluid/gas mixture, consisting of the liquid cooling fluid, and a gaseous phase of the cooling fluid/gas mixture, consisting of the evaporated cooling fluid and the gas, are separated from each other. Details regarding the layout and the function of the phase separator are sufficiently well known to the person versed in the art and therefore will not be further explained in this place.

Thus, the use of the phase separator makes it possible to separate the liquid and the gaseous phase after the transfer of the thermal energy. The gaseous phase can be taken away to the surroundings. Thus, the gas or the ambient air may not be returned to the charging station and may not be recycled, since the gaseous phase after the transfer of the thermal energy is laden with cooling fluid vapor and fresh ambient air is better suited for a new use in this context.

In addition or alternatively, the liquid phase may be supplied to the liquid cooling fluid prior to the transfer of the thermal energy. The liquid phase goes through a circulation by which a “half-open system” is realized, insofar as the gaseous phase is taken away to the surroundings. Although the liquid phase can be taken to the cooling fluid reservoir of the charging station or a cooling fluid line at the charging station side, the liquid phase can be taken to the liquid cooling fluid at the motor vehicle side, such as by feeding it directly into the cooling element or a cooling fluid line leading to the cooling element. Thus, in this case, a return line for the liquid phase from the motor vehicle to the charging station is not absolutely essential. Thanks to the cooling fluid circulating at the motor vehicle side, the quantity of cooling fluid which has to be carried by means of the cooling fluid connection between the motor vehicle and the charging station is reduced, so that the connection line to form the cooling fluid connection can be smaller in dimension.

Some embodiments relate to a motor vehicle, comprising at least one electric energy accumulator, an electric interface, such as a charging socket, to form a detachable electrical connection, by means of which electric energy can be transferred from a charging station external to the motor vehicle to the energy accumulator, and a cooling fluid interface, such as a connection nozzle, to form a detachable cooling fluid connection, by means of which a cooling fluid can be taken from the charging station to at least one cooling element of the motor vehicle, so that thermal energy can be transferred from the energy accumulator via the cooling element to the cooling fluid and taken away by means of the cooling fluid. The motor vehicle described herein is adapted to carry out the method as described above.

In a first embodiment of a motor vehicle, it is provided that this comprises a gas delivery device, by means of which the liquid cooling fluid can be brought together with the gas before and/or during the feeding to the cooling element.

In a modification of this, the cooling fluid/gas mixture can be discharged directly into the surroundings after the transfer of the thermal energy. In particular, the motor vehicle comprises in this regard a mixture drain line, leading from the cooling element to a mixture outlet opening of the motor vehicle, by which the cooling fluid/gas mixture is discharged from the cooling element into the surroundings. The mixture outlet opening can be situated, for example, in the area of the underbody or the outer panel of the motor vehicle, and be covered by a hood or the like.

Insofar as the gas delivery device is provided in the motor vehicle as described herein, this may draw in ambient air as the gas via an intake opening of the motor vehicle and then supply this to the liquid cooling fluid via an air duct, which leads from the intake opening to the cooling element and/or to a cooling fluid line leading to the cooling element, at the motor vehicle side. The arrangement of the gas delivery device at the motor vehicle side has the advantage that the gas or the ambient air does not have to be taken from the charging station to the motor vehicle. A filter device can be provided in the area of the intake opening or connected after the intake opening, so that no foreign objects such as fallen leaves or insects or the like can be sucked in. The intake opening can be situated, for example, in the area of the underbody or the outer panel of the motor vehicle, and be covered by a hood or the like.

In a second embodiment of a motor vehicle, which can also be realized in combination with the first embodiment of the motor vehicle described herein, it is proposed that the motor vehicle comprises a phase separator, to which the cooling fluid/gas mixture can be taken partially or entirely and by means of which a liquid phase of the cooling fluid/gas mixture, consisting of the liquid cooling fluid, and a gaseous phase of the cooling fluid/gas mixture, consisting of the evaporated cooling fluid and the gas, can be separated from each other.

In one modification of this, the motor vehicle may comprise a liquid phase drain line, leading from the phase separator to the cooling element and/or to the or to a cooling fluid line leading to the cooling element, wherein the liquid phase can be supplied by means of the liquid phase drain line to the liquid cooling fluid at the motor vehicle side and prior to the transfer of the thermal energy. Thus, the liquid phase drain line closes a circuit in terms of the cooling fluid and produces the “partly open system” at the motor vehicle side, as already described above.

In addition or alternatively, it can be provided that the motor vehicle according to the second embodiment comprises a return connection interface, by means of which a detachable return connection can be formed, which connects the phase separator to the charging station, wherein the liquid phase can be taken by means of the return connection to the liquid cooling fluid at the charging station side. Here as well, a circuit is formed in terms of the cooling fluid in which the fluid circulates from the charging station to the motor vehicle and from the motor vehicle back to the charging station. The liquid phase can be taken to the liquid cooling fluid in the area of the cooling fluid reservoir or a cooling fluid line leading to a cooling fluid interface of the charging station. In this way, the cooling fluid and the liquid phase respectively have more time to cool down after the transfer of the thermal energy and until a further passage through the cooling element, which improves the cooling performance.

In addition or alternatively, it can be provided in the motor vehicle comprising the phase separator described herein that it comprises a gas phase drain line, leading from the phase separator to a gas phase drain opening of the motor vehicle, wherein the gaseous phase can be discharged via the gas phase drain line into the surroundings. The gas phase drain opening may be provided in any given place of the motor vehicle, for example in the area of the underbody or the outer panel, such as beneath a hood.

All of the features, benefits and aspects explained in connection with the method described herein hold equally for the motor vehicle described herein, and vice versa.

Some embodiments relate to a charging station for charging at least one electric energy accumulator of a motor vehicle, comprising an electric interface, in particular a charging cable having a plug, in order to form a detachable electrical connection, by means of which electric energy can be transferred from the charging station external to the motor vehicle to the energy accumulator, and a cooling fluid interface, in particular a hose having a connector plug, in order to form a detachable cooling fluid connection, by means of which a cooling fluid can be taken from the charging station to at least one cooling element of the motor vehicle, so that thermal energy can be transferred from the energy accumulator via the cooling element to the cooling fluid and taken away by means of the cooling fluid. The charging station described herein may be adapted to carry out the method as described above.

In regard to the interfaces, it can be provided that these, such as the charging cable and the hose, as well as any return connection, are assembled as a multi-strand connection line or a bundle. The plug associated with the electric interface and the connector plug associated with the cooling fluid interface as well as any plug associated with a return connection can be provided either as a single or as a combined multi-plug connection. Consequently, the lines provided can be connected individually, or bundled, to the motor vehicle.

In a first embodiment of a charging station it is provided that it comprises a gas delivery device, by means of which the liquid cooling fluid can be brought together with the gas before and/or during the feeding to the cooling element.

In a modification of this, it is proposed that the gas delivery device can draw in ambient air as the gas via an intake opening of the charging station. In the region of the intake opening are connected afterwards to the intake opening there can be provided a filter device, so that no foreign objects such as fallen leaves or insects or the like can be sucked in. The intake opening can be situated, for example, at the side at the charging station.

The ambient air drawn in can be supplied to the liquid cooling fluid via an air duct, connecting the intake opening to a cooling fluid line leading to the cooling fluid interface, at the charging station side. In addition or alternatively, it can be provided that the charging station comprises a gas connection interface, by means of which a detachable gas connection can be formed, connecting the intake opening to the cooling element and/or to a cooling fluid line of the motor vehicle leading to the cooling element, wherein the gas can be supplied by means of the gas connection to the liquid cooling fluid at the motor vehicle side.

In the context of the gas, a separate gas collection tank may be provided within and/or in the zone of the charging station, from which the gas intended for mixing in with the cooling fluid is provided.

In a second embodiment of a charging station it is provided that it comprises a phase separator, to which the cooling fluid/gas mixture can be taken partially or entirely and by means of which a liquid phase of the cooling fluid/gas mixture, consisting of the liquid cooling fluid, and a gaseous phase of the cooling fluid/gas mixture, consisting of the evaporated cooling fluid and the gas, can be separated from each other.

The charging station may comprise a liquid phase drain line, leading from the phase separator to a cooling fluid reservoir and/or to the or to a cooling fluid line leading to the cooling fluid interface, wherein the liquid phase can be supplied by means of the liquid phase drain line to the liquid cooling fluid at the charging station side and prior to the transfer of the thermal energy. In addition or alternatively, it can be provided that the charging station comprises a gas phase drain line, which leads from the phase separator to a gas phase drain opening of the charging station, wherein the gaseous phase can be discharged by means of the gas phase drain line into the surroundings.

All of the features, benefits and aspects explained in connection with methods described herein hold equally for charging station systems described herein, and vice versa.

### BRIEF DESCRIPTION OF THE SEVERAL VIEWS OF THE DRAWINGS

Further benefits and details will emerge from the embodiments described in the following, as well as the figures.

FIG. 1 shows an arrangement comprising a motor vehicle and a first embodiment of a charging station to explain a first embodiment of a method.

FIG. 2 shows an arrangement comprising a first embodiment of a motor vehicle and a charging station to explain a second embodiment of a method.

FIG. 3 shows an arrangement comprising a motor vehicle and a second embodiment of a charging station to explain a third embodiment of a method.

FIG. 4 shows an arrangement comprising a second embodiment of a motor vehicle and the first embodiment of the charging station to explain a fourth embodiment of a method.

FIG. 5 shows an arrangement comprising a third embodiment of a motor vehicle and a charging station to explain a fifth embodiment of a method.

FIG. 6 shows an arrangement comprising a motor vehicle and a third embodiment of a charging station to explain a sixth embodiment of a method.

### DETAILED DESCRIPTION

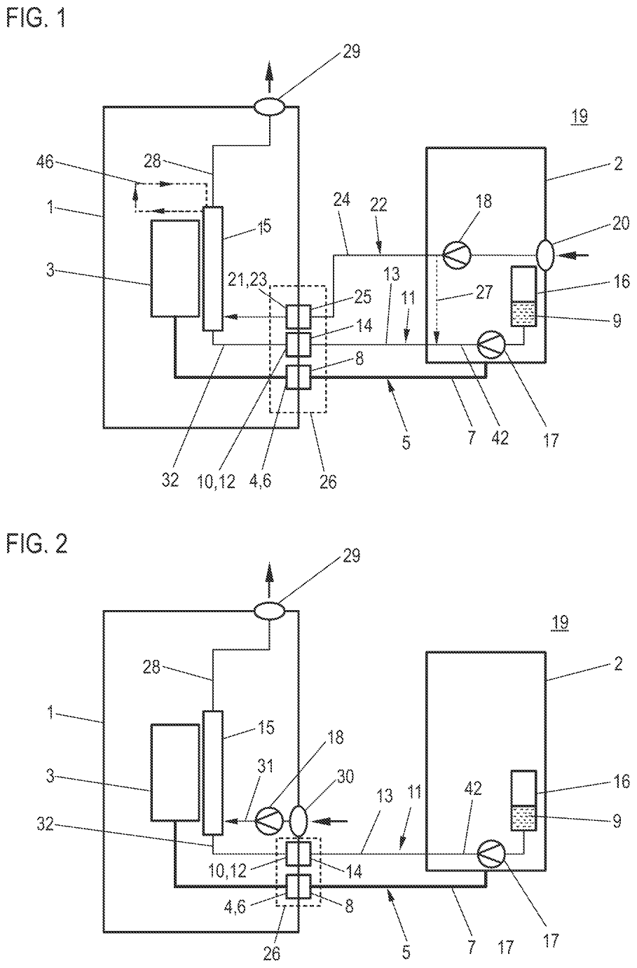

The highly schematic FIGS. 1 to 6 each show an arrangement of a motor vehicle 1 and a charging station 2 in the context of several embodiments. What is said about the individual figures holds equally for the other respective figures, unless otherwise explicitly stated.

The motor vehicle 1 shown in FIG. 1 is an electric vehicle having an electric energy accumulator 3 as the traction battery. The motor vehicle 1 in the state shown in FIG. 1 is electrically connected detachably to the charging station 2 for the charging of the energy accumulator 3. The charging station 2 is a stationary charging column, not being represented further in FIG. 1, and is connected to an energy source, such as a public electricity grid and/or to a solar installation and/or the like.

In order to form the detachable electrical connection between the motor vehicle 1 and the charging station 2, there is provided at the motor vehicle 1 side an electric interface 4 and at the charging station 2 side an electric interface 5. The electric interface 4 at the motor vehicle side is configured as a charging socket 6 and the electric interface 5 at the charging station side is configured as a charging cable 7 with a plug 8 which can be inserted into the charging socket 6. Although in the embodiments shown the charging cable 7 is firmly connected to the charging station 2 and thus is a component thereof, the charging cable 7 may be a separate component, produced at both ends to form a corresponding plug connection, namely on the one side with the motor vehicle 1 and on the other side with the charging station 2.

The motor vehicle 1 is connected to the charging station 2 moreover across a detachable cooling fluid connection, by means of which a cooling fluid 9 can be taken from the charging station 2 to the motor vehicle 1. In the present instance, water is used as the cooling fluid 9. In order to form the cooling fluid connection, a cooling fluid interface 10 of the motor vehicle 1 and a cooling fluid interface 11 of the charging station 2 are provided. The cooling fluid interface 10 at the motor vehicle side is configured as a connection nozzle 12 and the cooling fluid interface 11 at the charging station side is configured as a hose 13 having a connector plug 14 which can be inserted into the connection nozzle 12.

By means of the cooling fluid connection, the cooling fluid 9 can be taken from the charging station 2 to a cooling element 15 of the motor vehicle 1. The cooling element 15 in the embodiments is configured as a cooling plate standing in thermal contact with the energy accumulator 3, through which cooling ducts not otherwise represented run. The cooling fluid 9 flows through the cooling ducts after being supplied to the cooling element 15. In this process, thermal energy is transferred from the energy accumulator 3 to the cooling element 15 and from the cooling element 15 in turn to the cooling fluid 9, so that a cooling of the energy accumulator 3 occurs during the charging process of the motor vehicle 1.

As regards the cooling element 15, this may be a heat exchanger, which is incorporated in a cooling circuit 46 provided independently of the charging station at the motor vehicle 1 side. The cooling circuit 46 is shown by broken line in FIG. 1, omitting any further components involved in it. A coolant circulates in the cooling circuit 46, so that thermal energy is transferred from the energy accumulator 3 to a cooling plate standing in thermal contact with the energy accumulator 3, being included in the cooling circuit 46 and having the coolant flowing through it. The coolant then flows through the heat exchanger, whereby the heat is transferred to the cooling fluid 9 flowing through the heat exchanger.

The cooling circuit 46 of the motor vehicle 1 can be provided exclusively for the transfer of thermal energy from the energy accumulator 3 to the cooling element 15. Alternatively, the cooling circuit 46 can be provided as an active cooling circuit, where “active” means that a further cooling effect with regard to the coolant also occurs in the cooling circuit 46 itself, apart from the cooling element 15. Thus, the cooling circuit 46 can work on the model of a refrigerating machine. A further heat exchanger can be incorporated in the cooling circuit 46, which is itself coupled to a refrigerant circuit. The cooling circuit 46 can comprise a further heat exchanger, in which the coolant is cooled for example by means of air cooling. The cooling circuit 46 can be designed and provided, in particular, for cooling the energy accumulator 3 in a driving operation of the motor vehicle 1. The cooling effect realized by means of the cooling circuit 46 is correspondingly intensified during the charging process in the method described herein.

The energy accumulator 3 may stand in thermal contact with at least one additional cooling element not represented in the figures, which in turn is incorporated in a separate cooling circuit. In this case, the cooling element 15 is used in addition to the further cooling element, not shown, for the temperature control of the energy accumulator 3, wherein both cooling elements can work independently of and separately from each other, since they are incorporated in different cooling circuits.

The charging station 2 comprises a cooling fluid reservoir 16, provided as a water tank, the cooling fluid 9 contained therein being taken by means of a cooling fluid delivery device 17, designed as a pump, from the cooling fluid reservoir 16 to the cooling element 15. Alternatively to the cooling fluid reservoir 16, it can be provided that the charging station 2 is connected to a cooling fluid source, such as a public water supply grid. This can also be the case in the embodiments shown here, so that the cooling fluid reservoir 16 is automatically replenished as soon as the level of the cooling fluid 9 in the cooling fluid reservoir 16 falls below a predetermined minimum level. Furthermore, it can be provided that the cooling fluid reservoir 16 of the charging station 2 can be replenished by means of a rain water catchment and/or a pump installation, by means of which water can be drawn from a local aquifer or from ground water.

Regarding the method described herein, the liquid cooling fluid 9 may be brought together with a gas before or during the feeding to the cooling element 15, so that the liquid cooling fluid 9 forms together with the gas a cooling fluid/gas mixture. The gas used in the present instance is ambient air. Thus, the cooling element 15 receives not only the liquid cooling fluid 9, but also the two-phase mixture comprising the liquid cooling fluid 9 and the gas. This has the effect that, when the thermal energy is transferred from the cooling element 15 to the cooling fluid 9, at least a portion of the cooling fluid 9 is evaporated into the gas. Otherwise put, a portion of the liquid cooling fluid 9 beneath the boiling temperature of the cooling fluid 9 is transformed into the gaseous state, so that the gas becomes enriched in the gaseous cooling fluid 9. Specifically, the water vapor content increases for the ambient air present in the mixture. Additional energy is required during the evaporation process to bring about a cooling effect in regard to the coolant 9, so that ultimately the cooling effect of the cooling fluid 9 on the cooling element 15 or the energy accumulator 3 is heightened.

The gas is taken to the liquid cooling fluid 9 by means of a gas delivery device 18. In the present case, this is a gas delivery pump or a fan for drawing in air from the surroundings 19. The gas delivery device 18 in the embodiment shown in FIG. 1 is a component of the charging station 2, while the feeding of the gas to the cooling fluid 9 occurs via a gas connection, by which the motor vehicle 1 and the charging station 2 are detachably connected to each other. The charging station 2 has an intake opening 20, by which the ambient air can be drawn in as the gas by means of the gas delivery device 18. In order to form the gas connection, the motor vehicle 1 comprises a gas connection interface 21 and the charging station 2 comprises a gas connection interface 22. The gas connection interface 21 at the motor vehicle side is configured as a connection nozzle 23 and the gas connection interface 22 at the charging station side is configured as a hose 24 having a connector plug 25, which can be inserted into the connection nozzle 23. In place of the gas connection, it can be provided that the gas is supplied to the liquid cooling fluid 9 via an air duct 27, which connects the intake opening 20 to a cooling fluid line 42 of the charging station 2 leading to the cooling fluid interface 11, at the charging station side. The air duct 27 is indicated by a broken-line arrow in FIG. 1. In this case, the gas connection and the corresponding interfaces 21, 22 are eliminated.

The components 6, 8, 12, 14, 21 and 25 of the plug connections described in the context of FIG. 1 can be provided as a common plug connection 26, so that a user when connecting the motor vehicle 1 to the charging station 2 does not need to hook up multiple plugs separately, but only a single plug. The common plug connection 26 is indicated schematically in the figures by the broken-line box. The charging cable 7 as well as the hoses 13, 24 may also be in this case combined or bundled into one common multistrand connection line. As already explained above in connection with the charging cable 7, the common connection line may be a separate component, configured to form a common plug connection at both ends, namely, to the motor vehicle 1 on the one hand and to the charging station 2 on the other hand.

In regard to FIG. 1, the cooling fluid/gas mixture after the transfer of the thermal energy is discharged entirely into the surroundings 19. For this, the cooling element 15 is connected via a mixture drain line 28 to a mixture outlet opening 29 of the motor vehicle 1. The draining of the mixture into the surroundings 19 is particularly free of problems, because it is a two-phase mixture of water and air enriched in water vapor, which is neither toxic nor harmful to the environment. The mixture outlet opening 29 is situated in the area of the outer skin of the motor vehicle 1, such as beneath a hood, or in the area of the motor vehicle underbody.

In the following, the arrangement shown in FIG. 2 will be explained, and it corresponds to the arrangement shown in FIG. 1, except for the differences explained below. These systems differ in that the gas delivery device 18 is a component of the motor vehicle 1. Accordingly, the gas delivery device 18 can draw in ambient air as the gas via an intake opening 30 of the motor vehicle 1 and then supply it to the liquid cooling fluid 9 via an air duct 31, which leads from the intake opening 30 to the cooling element 15, at the motor vehicle side. In addition or alternatively, the air duct 31 can also lead from the intake opening 30 to a cooling fluid line 32 leading to the cooling element 15.

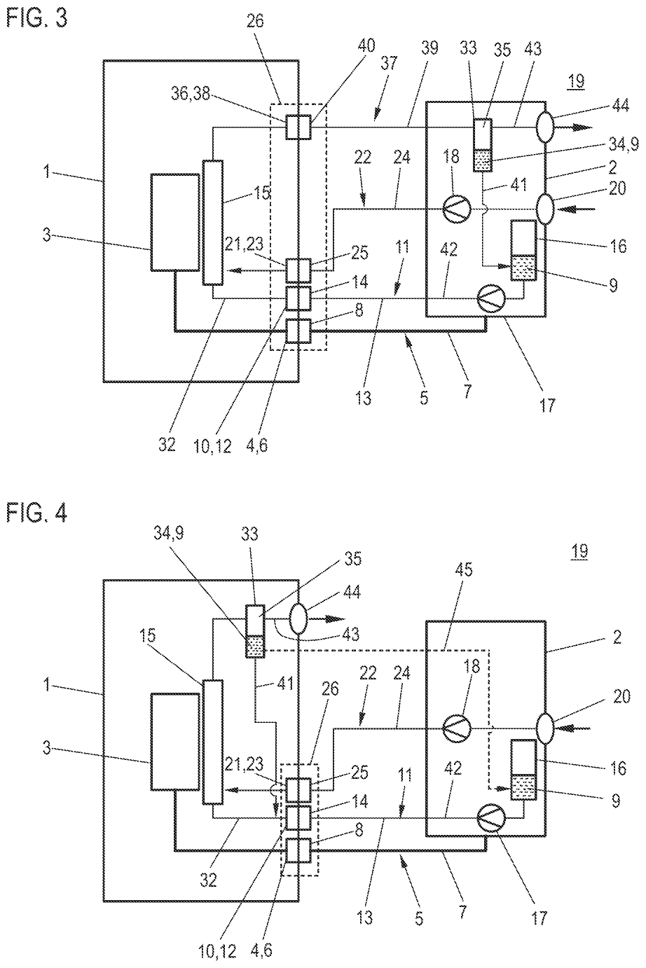

Referring to FIG. 3, a third arrangement with the motor vehicle 1 and the charging station 2 will be explained. By contrast with FIG. 1, in this embodiment it is provided that the cooling fluid/gas mixture after the transfer of the thermal energy is taken to a phase separator 33 of the charging station 2, by means of which a liquid phase 34 of the cooling fluid/gas mixture, consisting of the liquid cooling fluid 9, and a gaseous phase 35, consisting of the evaporated cooling fluid 9 and the gas, are separated from each other. Thus, the cooling fluid/gas mixture is not given off to the surroundings 19, as in FIGS. 1 and 2, but rather it is taken back to the charging station 2 via a detachable return connection connecting the motor vehicle 1 and the charging station 2.

In order to form the return connection, the motor vehicle 1 comprises a return connection interface 36 and the charging station 2 comprises a return connection interface 37. The return connection interface 36 at the motor vehicle side is configured as a connection nozzle 38 and the return connection interface 37 at the charging station side is configured as a hose 39 having a connector plug 40. The plug connection formed by means of the connection nozzle 38 and the connector plug 40 can also be formed in the context of the common plug connection 26. The hose 39, moreover, can be part of the multistrand common connection line comprising the components 7, 13, 24.

In the embodiment of FIG. 3, the charging station 2 comprises a liquid phase drain line 41, which leads from the phase separator 33 to the cooling fluid reservoir 16 and by which the liquid phase 34 is again taken to the liquid cooling fluid 9 at the charging station side. In addition or alternatively, the liquid phase drain line 41 can lead from the phase separator 33 to a cooling fluid line 42 leading from the cooling fluid reservoir 16 to the cooling fluid interface 11. Moreover, the charging station 2 comprises a gas phase drain line 43, which leads from the phase separator 33 to a gas phase drain opening 44 of the charging station 2, the gaseous phase 35 being discharged by means of the gas phase drain line 43 via the gas phase drain opening 44 into the surroundings 19. As regards the hose 24 provided in this embodiment or the gas connection, the gas can instead be taken to the liquid cooling fluid 9, as already explained in connection with FIG. 1, via the air duct 27, which connects the intake opening 20 to the cooling fluid line 42 of the charging station 2 leading to the cooling fluid interface 11, at the charging station side.

In the following, reference is made to FIG. 4, comprising a further arrangement comprising the motor vehicle 1 and the charging station in the configuration already shown in FIG. 1. The arrangement corresponds to the system shown in FIG. 3, but with the difference that the phase separator 33 is a component of the motor vehicle 1. Thus, the detachable return connection is not provided for this arrangement, but instead the motor vehicle 1 comprises the liquid phase drain line 41, which leads from the phase separator 33 to the cooling fluid line 32 leading to the cooling element 15, so that the liquid phase 34 is taken to the liquid cooling fluid 9 at the motor vehicle side before the transfer of the thermal energy. The liquid phase drain line 41 can also lead directly to the cooling element 15. Moreover, the motor vehicle 1 comprises the gas phase drain line 43, which leads from the phase separator 33 to the gas phase drain opening 44 of the motor vehicle 1, the gaseous phase 35 being taken across the gas phase drain line 43 and the gas phase drain opening 44 to the surroundings 19.

Regarding the liquid phase 34, it can be alternatively provided that this is returned to the charging station 2 or to the cooling fluid reservoir of the charging station 2 across a detachable return connection connecting the motor vehicle 1 and the charging station 2, as was described in connection with FIG. 3. This connection is indicated in FIG. 4 by means of the broken-line arrow 45, while details regarding the interfaces 36, 37 are not shown for sake of clarity.

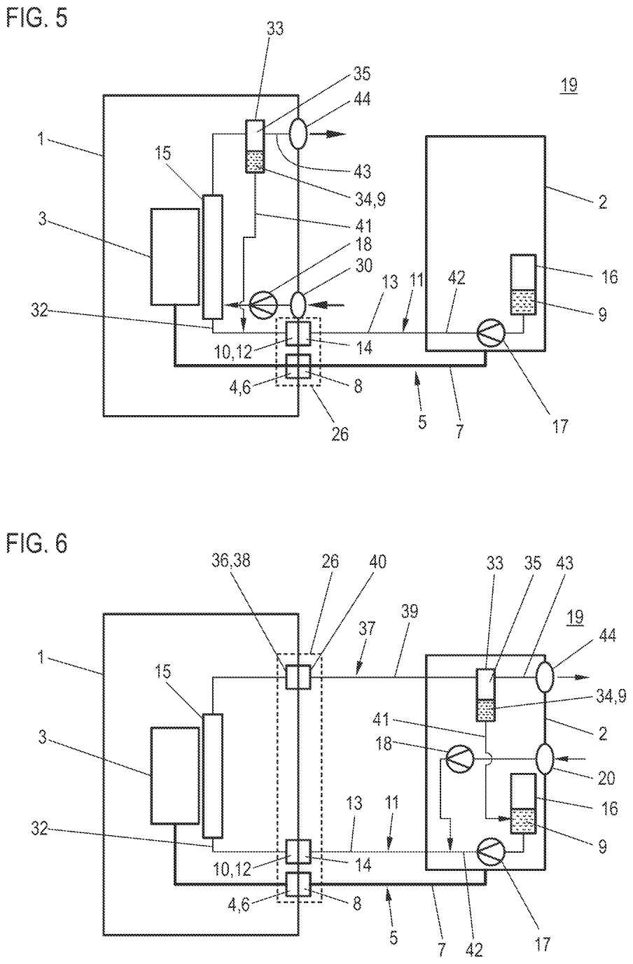

The arrangement shown in FIG. 5 corresponds to the arrangement shown in FIG. 4, but with the difference that the gas delivery device 18 is not a component of the charging station 2, but rather of the motor vehicle 1. Accordingly, what was explained in this regard in connection with FIG. 2 holds equally for the motor vehicle 1 and system of FIG. 5.

The arrangement shown in FIG. 6 corresponds to a modification of the arrangement shown in FIG. 3, which differ from each other in that in FIG. 3 the gas connection is formed by means of the interfaces 21, 22 between the motor vehicle 1 and the charging station 2, while in FIG. 6 the gas is taken by means of the gas delivery device 18 to the cooling fluid line 42, which leads to the cooling fluid interface 11 at the charging station side. Thus, the gas is not taken to the cooling fluid 9 at the motor vehicle side, but already at the charging station side. Apart from the cooling element 15, all the components needed for the cooling process, such as the phase separator 33 or the delivery pump or gas delivery device 18, are accommodated at or inside the charging station 2 external to the motor vehicle, so that the entire technology and functionality of the cooling fluid conditioning and preparation is provided outside the motor vehicle.

German patent application no. 10 2021 132151.4, filed Dec. 7, 2021, to which this application claims priority, is hereby incorporated herein by reference, in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A method for charging at least one electric energy accumulator of a motor vehicle, comprising:
transferring electric energy from a charging station external to the motor vehicle via a detachable electrical connection to the energy accumulator, wherein a cooling fluid is taken from the charging station via a detachable cooling fluid connection to at least one cooling element of the motor vehicle, so that thermal energy from the energy accumulator is transferred via the cooling element to the cooling fluid and taken away by the cooling fluid, wherein the liquid cooling fluid is mixed with a gas before and/or during its transfer to the cooling element, so that a cooling fluid/gas mixture is formed, wherein at least a portion of the cooling fluid is evaporated into gas during the transfer of the thermal energy from the energy accumulator to the cooling fluid.

2. The method according to claim 1, wherein water is used as the cooling fluid and/or ambient air is used as the gas.

3. The method according to claim 1, wherein the charging station comprises a cooling fluid reservoir and/or it is connected to a cooling fluid source, wherein the cooling fluid is taken by a cooling fluid delivery device from the cooling fluid reservoir or the cooling fluid source to the cooling element.

4. The method according to claim 1, wherein gas is supplied to the cooling fluid by a gas delivery device, the gas delivery device being a component of the motor vehicle or the charging station.

5. The method according to claim 1, wherein the cooling element is a cooling plate standing in thermal contact with the energy accumulator or a heat exchanger by which thermal energy is transferred from a coolant circulating in a cooling circuit for the cooling of the energy accumulator to the cooling fluid.

6. The method according to claim 1, wherein the cooling fluid/gas mixture is partially or entirely discharged into the surroundings after the transfer of the thermal energy.

7. The method according to claim 1, wherein the cooling fluid/gas mixture is partially or entirely taken to a phase separator of the motor vehicle or the charging station after the transfer of the thermal energy, wherein a liquid phase of the cooling fluid/gas mixture, consisting of the liquid cooling fluid, and a gaseous phase of the cooling fluid/gas mixture, consisting of the evaporated cooling fluid and the gas, are separated from each other.

8. The method according to claim 7, wherein the gaseous phase is discharged into the surroundings and/or the liquid phase is supplied to the liquid cooling fluid prior to the transfer of the thermal energy.

9. A motor vehicle, comprising:
at least one electric energy accumulator, and
an electric interface, especially a charging socket, to form a detachable electric connection, by which electric energy can be transferred from a charging station external to the motor vehicle to the energy accumulator, and a cooling fluid interface, especially a connection nozzle, to form a detachable cooling fluid connection, by which a cooling fluid can be taken from the charging station to at least one cooling element of the motor vehicle, so that thermal energy can be transferred from the energy accumulator via the cooling element to the cooling fluid and taken away by the cooling fluid, wherein the motor vehicle includes:
a gas delivery device configured to bring the liquid cooling fluid together with the gas before and/or during the feeding to the cooling element; and/or
a phase separator, to which the cooling fluid/gas mixture can be taken partially or entirely and which is configured to separate a liquid phase of the cooling fluid/gas mixture, consisting of the liquid cooling fluid, from a gaseous phase of the cooling fluid/gas mixture, consisting of the evaporated cooling fluid and the gas.

10. The motor vehicle according to claim 9, further comprising the gas delivery device, wherein the gas delivery device can draw in ambient air as the gas via an intake opening of the motor vehicle and then supply it to the liquid cooling fluid via an air duct, which leads from the intake opening to the cooling element and/or to a cooling fluid line leading to the cooling element, at the motor vehicle side.

11. The motor vehicle according to claim 9, having the phase separator, wherein the motor vehicle further comprises a liquid phase drain line, leading from the phase separator to the cooling element and/or to the cooling fluid line or a cooling fluid line leading to the cooling element, wherein the liquid phase can be supplied by the liquid phase drain line to the liquid cooling fluid at the motor vehicle side and prior to the transfer of the thermal energy, and/or
the motor vehicle further comprises a return connection interface by which a detachable return connection can be formed, which connects the phase separator to the charging station, wherein the liquid phase can be taken by the return connection to the liquid cooling fluid at the charging station side and/or
the motor vehicle further comprises a gas phase drain line, leading from the phase separator to a gas phase drain opening of the motor vehicle, wherein the gaseous phase can be discharged via the gas phase drain line into the surroundings.

12. The motor vehicle according to claim 9 wherein the electric interface is a charging socket, and the cooling fluid interface is a connection nozzle.

13. A charging station for charging at least one electric energy accumulator of a motor vehicle, comprising:
an electric interface, in particular a charging cable having a plug, in order to form a detachable electrical connection, by which electric energy can be transferred from the charging station external to the motor vehicle to the energy accumulator, and
a cooling fluid interface, in particular a hose having a connector plug, in order to form a detachable cooling fluid connection, by which a cooling fluid can be taken from the charging station to at least one cooling element of the motor vehicle, so that thermal energy can be transferred from the energy accumulator via the cooling element to the cooling fluid and taken away by the cooling fluid, wherein the charging station includes:
a gas delivery device, by which the liquid cooling fluid can be brought together with the gas before and/or during the feeding to the cooling element; and/or
a phase separator, to which the cooling fluid/gas mixture can be taken partially or entirely and by which a liquid phase of the cooling fluid/gas mixture, consisting of the liquid cooling fluid, and a gaseous phase of the cooling fluid/gas mixture, consisting of the evaporated cooling fluid and the gas, can be separated from each other.

14. The charging station according to claim 13, comprising the gas delivery device, wherein the gas delivery device can draw in ambient air as the gas via an intake opening of the motor vehicle, wherein
the gas can be supplied to the liquid cooling fluid via an air duct, which connects the intake opening to the cooling fluid line leading to the cooling fluid interface at the charging station side; and/or
the charging station further comprises a gas connection interface, by which a detachable gas connection can be formed, which connects the intake opening to the cooling element and/or to a cooling fluid line of the motor vehicle leading to the cooling element, wherein the gas can be supplied by the gas connection to the liquid cooling fluid at the motor vehicle side.

15. The charging station according to claim 13, having the phase separator, wherein
the charging station further comprises a liquid phase drain line, leading from the phase separator to a cooling fluid reservoir and/or to the or to a cooling fluid line leading to the cooling fluid interface, wherein the liquid phase can be supplied by the liquid phase drain line to the liquid cooling fluid at the charging station side and prior to the transfer of the thermal energy; and/or
the charging station further comprises a gas phase drain line, which leads from the phase separator to a gas phase drain opening of the charging station, wherein the gaseous phase can be discharged by the gas phase drain line into the surroundings.
